(19) United States
(12) Patent Application Publication
(10) Pub. No.: US 2019/0205484 A1
(43) Pub. Date: Jul. 4, 2019

(54) SYSTEMS AND METHODS FOR CONSTRUCTION PLANNING

(71) Applicant: ALICE Technologies, Inc., San Francisco, CA (US)

(72) Inventors: René Morkos, San Francisco, CA (US); Hossein Shahbazi, Palo Alto, CA (US); Carl Chatfield, Menlo Park, CA (US); Melvin Low, Mountain View, CA (US); Dimitrios Farmakis, Thessaloniki (GR); Dustin Calim, Atherton, CA (US)

(21) Appl. No.: 15/858,502

(22) Filed: Dec. 29, 2017

(30) Foreign Application Priority Data
Dec. 28, 2017 (GR) 20170100586

(51) Int. Cl. G06F 17/50; G06Q 10/06; G06Q 50/08

(52) U.S. Cl. CPC G06F 17/5004; G06Q 50/08; G06Q 10/06313

(57) ABSTRACT

Provided herein are systems and methods for construction planning. The systems and methods may utilize construction recipes and recipe relationships between the construction recipes. A construction recipe may comprise a formula for building a construction element, and comprise one or more construction operations logically related by one or more logical relationships. The same construction recipe may be assigned to construction elements of the same type. An operation can be defined by required resources drawn from a resource pool.

### CROSS-REFERENCE

This application claims the benefit of Greek Application No. 20170100586, filed Dec. 28, 2017, in Greece, which application is entirely incorporated herein by reference.

### BACKGROUND

A construction process can vary significantly depending on the scope and complexity of the construction project. For example, construction can be of a residential, industrial, commercial, recreational, civil, public, private, or other nature, or a combination thereof. The construction process can involve distinct or overlapping processes, phases, or stages, such as designing, planning, scheduling, building, operation, and maintenance. These processes can occur pre-construction, post-construction, and/or during construction. The processes may or may not be carried out in sequential order. For example, one process can be a pre-requisite to another process, such as designing being a pre-requisite to planning, and planning being a pre-requisite to scheduling. In another example, a plurality of processes can happen in parallel, entirely or partially, such as designing and planning. In some instances, aspects of one process can be modified in view of or in response to another process. For example, a design of a construction object can be modified during a planning stage or a building stage.

### SUMMARY

A construction project can often be subject to limitations and constraints such as spatial constraints, temporal constraints, resource constraints, budget constraints, regulatory constraints, and other limitations that may or may not be interdependent on other limitations and constraints. If not managed properly, these limitations and constraints can lead to complications, hazards, inefficiency, waste of valuable resources and budget, or even complete or partial failure of the construction project. Thus recognized herein is a need for systems and methods for construction planning that address the aforementioned drawbacks.

Provided herein are systems and methods for construction planning. The systems and methods can receive and analyze a data file defining a three-dimensional (3D) model of construction elements and/or an assembly thereof. The 3D model can be a computer data file, such as a building information modeling (BIM) data file or a computer-aided design (CAD) data file. During analysis, the systems and methods can categorize construction elements, such as into shapes, determine one or more dimensions pertaining to the construction elements, and perform a mesh analysis to determine support relationships between the construction elements. The support relationships between the construction elements may form a network of relationships mapping out the 3D model. A support relationship can define, for example, which one or more elements support which one or more other elements. A support relationship can be a logical constraint.

The systems and methods for construction planning can involve (i) modification of support relationships between the construction elements, (ii) grouping and splitting of construction elements, and/or (iii) use of a construction recipe library. The construction recipe library can comprise a plurality of recipes, each recipe comprising a formula for building a specific type of construction element. The formula can define one or more operations (e.g., place formwork, place steel, pour concrete, dry concrete, remove formwork, etc.) and sequence thereof for building the construction element. An operation can define one or more resources (e.g., raw material, labor, etc.), production rate, spatial requirements, temporal requirements, and/or other instructions or factors for the operation. The formula may be dependent on one or more parameters (e.g., material, dimensions, etc.) of the specific type of construction element. The same recipe can be used to plan the building of the same type of construction element. In some instances, different recipes may exist for the same type of construction element and may be selected manually by a user or automatically (e.g., by a computer algorithm). A new recipe can be created and saved in the construction recipe library for new types of construction elements. A recipe can be constrained by available resources, such as in a resource pool which is described further below.

The plurality of recipes in the construction recipe library may or may not be interlinked via one or more recipe relationships. For example, a first recipe can be linked to a second recipe via a recipe relationship. A recipe can be linked to a plurality of recipes. A recipe relationship can be a logical constraint. The recipe relationship can define a sequential relationship, such as to identify which recipe is to be performed first, which recipe is to be performed after, which recipes are to be performed in parallel, which recipe is to be performed at a particular time (e.g., 45 minutes in, etc.), step, operation, phase, stage, point, duration, and/or other unit relative to another recipe, and other sequential relationships. A recipe relationship can be a relationship between operations that are in different recipes. A recipe relationship can link a recipe to external recipes, such as for building at another location.

The systems and methods may provide a resource pool for a construction project. The resource pool can define the available resources for the construction project, such as labor (e.g., skill set in labor pool, standard work week, available dates, cost, etc.), equipment (e.g., location, reach, available time, efficiency, cost, etc.), materials (e.g., amount, type, cost, etc.), space (e.g., area, volume, height, equipment allowed in space, available time, labor allowed in space (e.g., maximum number of adults), cost, etc.), production rates (e.g., rates at which operations are carried out, etc.), work weeks (e.g., hours a week per crew, hours a week per individual, etc.), and other resources. Some resources, such as space and production rates can be global variables that are accessible from any recipe in the construction recipe library. A recipe may draw parameters and resources from the resource pool. For example, the resource pool can present a constraint on the recipe.

The systems and methods may provide comprehensive construction planning for a construction project using the abovementioned tools, such as construction recipes, recipe relationships, and/or the resource pool. In some instances, the construction planning can be completed prior to or during construction scheduling. In an example, the construction planning can create and/or define one or more plans that need to be scheduled. In some instances, scheduling can refer to plotting at least part of a construction plan (e.g., operation) to a timeline, such as assigning a start and end time (and/or date). The construction planning and/or scheduling can be modified or updated in real-time, such as by modifying or updating one or more parameters of the construction plan. Upon modification or update, the construction project can be re-planned and/or re-scheduled. The parameters that can be modified or updated can include parameters, such as parameters of available resources in the resource pool and/or properties (e.g., amount, type, cost, etc.) thereof and parameters of the construction method (e.g., recipe, recipe relationship, support relationship, etc.) and/or properties thereof

The construction planning and scheduling thereof can be visualized on a graphical user interface. For example, the planning and/or scheduling can be visualized as a plot, graph, table, or other charts showing information such as cost and duration (e.g., as axes in a graph, columns in a table, etc.). In another example, the planning and/or scheduling can be visualized as a three-dimensional (3D) visual output showing a time-dependent 2D cross-sectional output progress. In another example, the planning and/or scheduling can be visualized as a four-dimensional (4D) visual output showing a time-dependent 3D output progress, such as a 4D Gantt chart. The visualization may be filtered by different factors, resources, and/or other parameters. The construction planning and scheduling can be presented on a dynamic user interface, such as having one or more user interactive objects (e.g., slider bar). In some instances, the construction planning and scheduling can be visualized as information cards, such as by time, crew, operation, and/or construction element.

In an aspect, provided is a computer-implemented method for construction planning, comprising: receiving, over a computer network, at a computer system programmed to facilitate construction planning, a data file defining a 3D model of a construction object, wherein the construction object comprises one or more construction elements; determining a type and dimension values for each construction element; identifying support relationships between the one or more construction elements; assigning a construction recipe to each construction element, wherein the construction recipe defines a formula for building the construction element, wherein the formula comprises one or more operations that are logically related by one or more logical relationships, wherein an operation is defined at least by required resources, and wherein a same construction recipe is assigned to a same type of construction element; defining recipe relationships between different construction recipes for different construction elements, wherein the recipe relationship is based at least in part on the support relationships; and providing, over the computer network, to a user a construction plan comprising a plurality of construction recipes that are logically related by a plurality of recipe relationships.

In some embodiments, the method can further comprise displaying the construction recipe on a graphical user interface, each operation visualized as an independent graphical representation. In some embodiments, the method can further comprise displaying the recipe relationships on a graphical user interface, each recipe relationship visualized as an independent graphical representation. In some embodiments, the method can further comprise displaying the logical relationships on a graphical user interface, each logical relationship visualized as an independent graphical representation.

In some embodiments, the required resources can be constrained by a resource pool, accessible by the computer system, defining available resources.

In some embodiments, the required resources can be at least one of duration, production rate, equipment, material, and labor.

In another aspect, provided is a non-transitory computer-readable medium comprising machine-executable code that, upon execution by one or more computer processors, implements a method for sharing location specific information, the method comprising: receiving, over a computer network, at a computer system programmed to facilitate construction planning, a data file defining a 3D model of a construction object, wherein the construction object comprises one or more construction elements; determining a type and dimension values for each construction element; identifying support relationships between the one or more construction elements; assigning a construction recipe to each construction element, wherein the construction recipe defines a formula for building the construction element, wherein the formula comprises one or more operations that are logically related by one or more logical relationships, wherein an operation is defined at least by required resources, and wherein a same construction recipe is assigned to a same type of construction element; defining recipe relationships between different construction recipes for different construction elements, wherein the recipe relationship is based at least in part on the support relationships; and providing, over the computer network, to a user a construction plan comprising a plurality of construction recipes that are logically related by a plurality of recipe relationships.

In some embodiments, the method can further comprise displaying the construction recipe on a graphical user interface, each operation visualized as an independent graphical representation. In some embodiments, the method can further comprise displaying the recipe relationships on a graphical user interface, each recipe relationship visualized as an independent graphical representation. In some embodiments, the method can further comprise displaying the logical relationships on a graphical user interface, each logical relationship visualized as an independent graphical representation.

In some embodiments, the required resources can be constrained by a resource pool, accessible by the computer system, defining available resources.

In some embodiments, the required resources can be at least one of duration, production rate, equipment, material, and labor.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1 illustrates an outline for a method for construction planning.

FIG. 2A shows a 3D model of an exemplary construction object.

FIG. 2B illustrates a partial support relationship network for the construction object of FIG. 2A.

FIG. 3 illustrates a user interface for viewing and/or modifying support relationships.

FIG. 4 illustrates a user interface for assigning construction recipes to construction elements in a construction object.

FIG. 5 illustrates a user interface for creating an operation in a recipe.

FIG. 6 illustrates a user interface for creating a recipe.

FIG. 7 illustrates a network of recipe relationships.

FIG. 8 illustrates a user interface for defining a resource pool for a construction project.

FIG. 9 illustrates a user interface for defining a space in a resource pool.

FIG. 10 illustrates a user interface for presenting a visualization of parametric scheduling.

FIG. 11 illustrates a user interface for presenting an enhanced Gantt chart for an exemplary construction schedule.

FIG. 12 illustrates an enlarged view of the information cards of FIG. 11.

FIG. 13 shows a computer control system that is programmed or otherwise configured to implement methods provided herein.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Provided herein are systems and methods for construction planning for a construction project. A construction project can be for any type of construction, such as for residential, industrial, commercial, recreational, civil, public, private, and/or other purposes. A construction project can involve any part of a construction process. For example, the construction project can involve one or more distinct or overlapping processes, phases, or stages, such as designing, planning, scheduling, building, operation, and maintenance. A construction project may not necessarily be limited to building a construction object. For example, the construction project can be for a demolition of a building or repairing of a building. In another example, the construction project can be for just laying the foundation, preparing a site for construction, and/or cleaning up a construction site.

The systems and methods for construction planning can involve different construction units, such as construction objects, construction elements, construction components, construction recipes, construction operations, and other construction tasks and construction methods. A construction object can be a physical structure, including physical infrastructure. A construction object can be an artificial structure. For example, a construction object can be a building, bridge, road, highway, gate, dam, wall, staircase, a part thereof, or any other physical structure. A construction object can be a plurality of buildings, bridges, roads, highways, gates, dams, walls, other structures, and/or a combination thereof. A construction object can be defined by one or more construction elements making up the construction object. A construction element can be any subset or unit of the construction object used for building or constructing the construction object. For example, a construction element can be a slab, a column, a wall, a beam, a block, a brick, a frame, an ingot, or any other subset or unit of a construction object. For instance, the construction object (e.g., building) can be a single construction element (e.g., column), a plurality of construction elements, and/or an assembly of a combination of construction elements (e.g., slabs, columns, etc.). A construction component can be one or more materials (e.g., raw, processed, etc.) that are used to form a construction element. For instance, a construction element (e.g., column) can comprise a plurality of construction components (e.g., concrete, formwork, and steel). In some instances, the construction object can be defined by a computer file, such as a building information modeling (BIM) data file or a computer-aided design (CAD) data file. The data file can be a three-dimensional (3D) data file. For example, the data file for a construction object can define a 3D model of the construction object. The data file for a construction object can define the construction elements of the construction object.

A construction recipe can be a formula for constructing a construction element (e.g., column, etc.). The construction recipe can comprise one or more construction operations (e.g., pouring cement, curing, etc.). Construction recipes can be saved in a construction recipe library, such as for future use.

The systems and methods for construction planning can involve one or more logical constraints, and/or logical relationships between the same or different construction units (e.g., construction object, construction element, construction recipe, construction operation, construction task, etc.). For example, there may exist one or more logical support relationships between construction elements of a construction object. Such support relationships can be extracted or determined from a data file of the construction object. There may exist one or more logical relationships between construction operations within a construction recipe or between different construction recipes. There may exist one or more logical recipe relationships between construction recipes of a construction element.

The systems and methods for construction planning can involve one or more adjustable parameters, such as for a construction unit. The systems and methods for construction planning can involve one or more fixed parameters. A parameter may be manually provided or adjusted by a user. A parameter may be pre-programmed or otherwise pre-determined by a computer system. A parameter may be automatically adjusted by a computer system, such as via one or more computer algorithms. A parameter can be for a construction resource, such as available labor, material, equipment, and/or space. A parameter can define a project constraint or requirement, such as spatial constraints, temporal constraints, quality constraints, and/or budget constraints. A parameter can be any adjustable factor. A parameter can be any fixed factor. In some instances, the available resources for a construction project can be saved in a resource pool common to one or more construction operations and/or construction recipes in the construction project. For example, a particular resource can be a global variable accessibly by all construction recipes in the construction project. Beneficially, the available resource can be coherently shared between the construction recipes without inadvertent double allocation of limited resources.

In some instances, the construction planning can be completed prior to or during construction scheduling. In an example, the construction planning can refer to creating and/or defining one or more plans that need to be scheduled. In some instances, scheduling can refer to plotting at least part of a construction plan (e.g., operation) to a timeline, such as assigning a start and end time (and/or date). The construction planning and/or scheduling can be modified or updated in real-time, such as by modifying or updating one or more parameters of the construction plan. Upon modification or update, the construction project can be re-planned and/or re-scheduled.

One or more aspects of the systems and methods for construction planning described above and further below can be implemented on a user interface, such as a construction planning platform. The user interface can be a graphical user interface. The user interface can be a dynamic user interface. The user interface can comprise one or more user interactive objects (e.g., buttons, sliders, hyperlinks, etc.). Advantageously, the systems and methods provided herein can provide a flexible user-controlled construction planning platform. By utilizing tools such as construction recipes, inter-recipe relationships, and the resource pool, among other tools described above and to be described further below, the systems and methods can facilitate accurate and efficient navigation and distribution of available resources.

Beneficially, the systems and methods for construction planning can allow users (e.g., involved in a construction project as workers, planners, managers, investors, owners, etc.) to flexibly plan a construction project, partially or entirely, before irreversibly committing expensive resources, such as materials, equipment, time, and labor. The systems and methods for construction planning described herein provide an improvement in computer-related technology, such as by defining specific rules and logical relationships (e.g., inter-recipe relationships, inter-elemental support relationships, intra-operation relationships, etc.) between construction units (e.g., construction elements, construction recipes, etc.) that have not previously been done before for construction planning. Furthermore, the construction planning and/or scheduling can be particularly visualized, filtered by part or as an overview, as a graphical representation (e.g., time-dependent 4D Gantt chart) to allow for more efficient presentation, translation, and data absorption or interpretation of construction planning data.

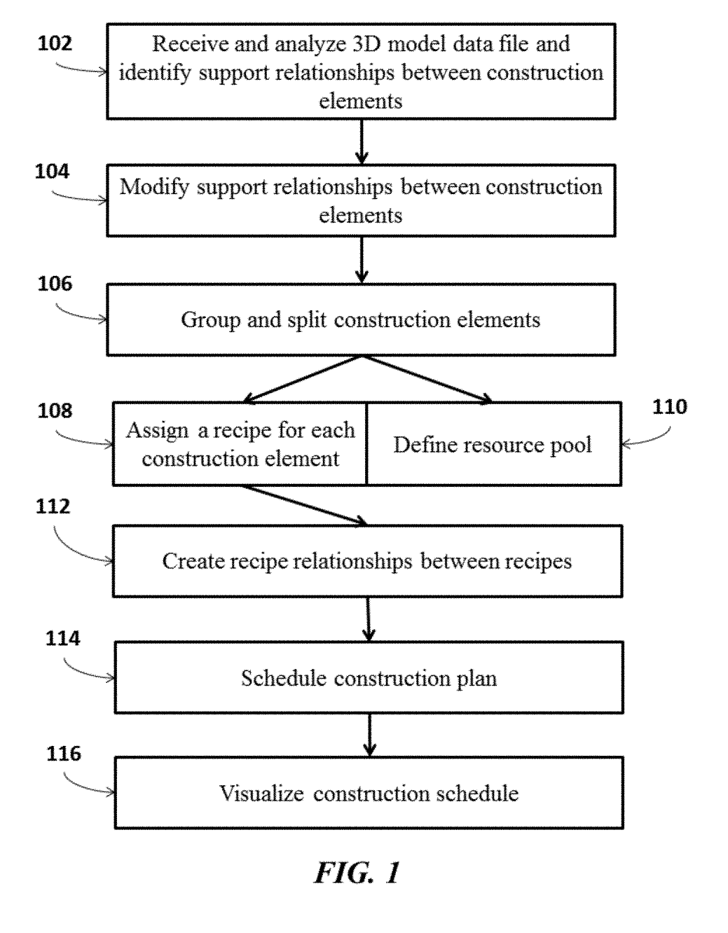

FIG. 1 illustrates an outline for a method for construction planning. A server, such as in a computer system for facilitating construction planning, can receive 102 a data file defining a 3D model of a construction object. For example, the data file can be a BIM data file or a CAD data file. The data file can be a file type supported by any existing construction or 3D model design software. The data file can be any other type of data file defining a 3D model. For example, the data file can be any data file defining a polygon mesh broken into elements. In some instances, the data file can be created by a user and uploaded to the server. In some instances, the data file can be pre-existing on the server and selected by the user. For example, the data file can be a template data file, such as a data file for a commonly used construction object that is offered for use to users by the server. While one server is mentioned, the computer system can comprise a plurality of servers that can individually or collectively perform the functions described above and further below. Any mention of “a server” performing one or more functions herein can refer to a plurality of servers acting individually or collectively to perform the one or more functions. Unless explicitly stated otherwise, all automated functions performed by the server described herein may be performed automatically by the server without user input, instructions, intervention, or other involvement.

The server can analyze 102 or otherwise process the data file defining the three-dimensional (3D) model or mesh data of the construction object, such as to identify and determine one or more construction elements of the construction object. The analysis, identification, and/or determination can be automated. The server can extract data about the one or more construction elements of the construction object. During analysis, the server can categorize construction elements, such as into shapes. For example, a construction element can have a shape of a cuboid, a sphere, a cylinder, or any other shape or form. The server can then determine one or more dimensions pertaining to the shape of the construction element. For example, a dimension can be a length, width, height, radius, diameter, altitude, depth, perimeter or any other dimension of a three-dimensional object. For example, a right cylinder can have the dimensions of a radius and a height. A sphere can have a single dimension of a radius. A cuboid can have the dimensions of length, height, and width. The server can then determine the respective values of the dimensions of the construction element. In some instances, the server may calculate or determine the respective values from other dimension values. In some instances, the server may determine a value for each dimension of the construction element. In some instances, the server may determine a value for only key dimensions of the construction element, such as the dimensions required for building.

Alternatively or in addition, the server can categorize construction elements into types, such as columns, walls, slabs, or other types of construction elements. In some instances, the type can be determined based at least on the shape. In some instances, the type can be user-defined in the data file. Alternatively or in addition, the type can be based on context of the construction element in the data file, such as based on an assembly or support relationship with another construction element, orientation, and/or arrangement. For example, two construction elements (e.g., slab, wall) having a similar shape of a substantially flat cuboid may be determined to be two different types based on their orientation and arrangement in the data file. Alternatively or in addition, the server can categorize construction elements by material or any other properties of the construction elements that can be extracted from the data file.

During analysis, the server can perform a mesh analysis to determine support relationships between the construction elements. A support relationship can define, for example, which one or more elements support which one or more other elements. For example an element can support another element. An element can support a plurality of other elements. An element can be supported by another element. An element can be supported by a plurality of other elements. A plurality of elements can be supported by a plurality of elements. A support relationship can be a logical constraint to the elemental configuration of the construction object. In some instances, the mesh analysis can be customized such that the mesh analysis is performed only on vertical adjacent planes, horizontal adjacent planes, select planes, or planes having certain angles. In some instances, the mesh analysis can be customized such that the mesh analysis is performed with different support tolerance. The mesh analysis can be customized with other parameters. The support relationships between the construction elements of a construction object may form a network of support relationships mapping out the 3D model of the construction object.

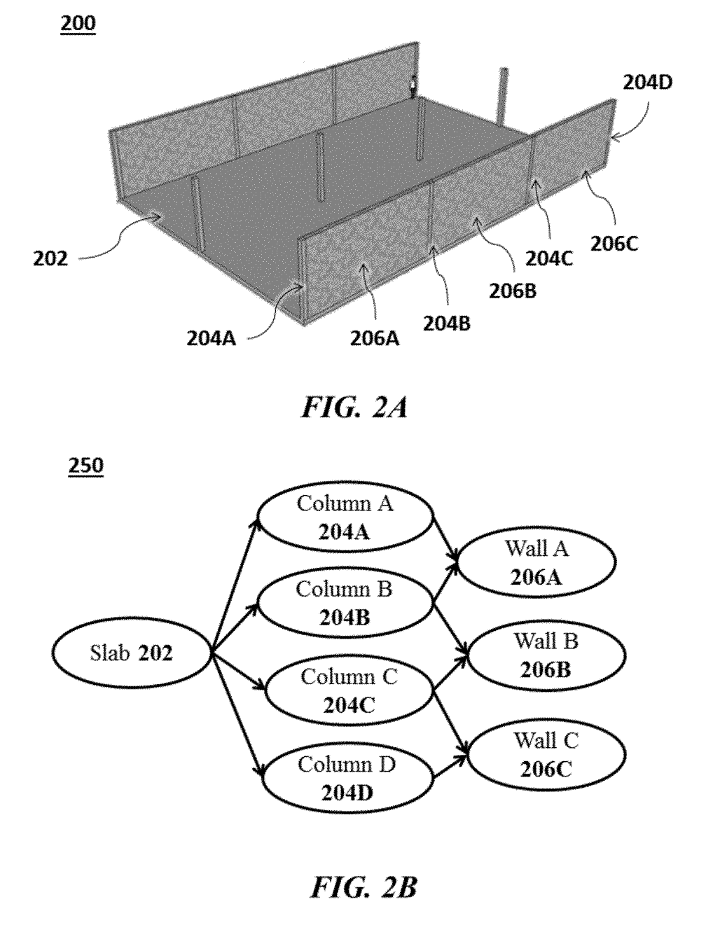

FIG. 2A shows a 3D model of an exemplary construction object. The exemplary construction object 200 can comprise a plurality of construction elements, such as slab type construction elements (e.g., slab 202), column type construction elements (e.g., columns 204A-D), and wall type construction elements (e.g., walls 206A-C). The exemplary construction object 200 can be a portion of a building. The server can receive a BIM data file defining the 3D model of the construction object 200. The server can analyze the BIM data file to extract data about the construction elements of the construction object. For example, for the construction object 200, the server may identify and determine from the data file that there are 1 slab type construction element (including slab 202), 12 column type construction elements (including columns 204A-D), and 6 wall type construction elements (including walls 206A-C). The server can then categorize each of the construction elements by shape and/or type (e.g., columns, walls, slabs, etc.) and determine one or more dimensions pertaining to the shape or type. The server can then determine the dimension value for each of the dimensions pertaining to the shape or type, or determine the dimension values for key dimensions pertaining to the shape or type. Thereafter, the server can determine one or more support relationships between the different construction elements.

FIG. 2B illustrates a partial support relationship network 250 for the construction object 200 of FIG. 2A. The server may perform a mesh analysis on the data file to determine the construction element. In some instances, the mesh analysis can be customized to analyze the construction elements and support relationships thereof adjoining vertical planes, such as the plane containing walls 206A-C. Upon analysis, the server may determine the partial support relationship network 250, where each block represents a construction element arrow represents a support relationship. For example, in the network 250, there exists a support relationship between the slab 202 and Column A 204A, the slab 202 and Column B 204B, the slab 202 and Column C 204C, the slab 202 and Column D 204D, Column A 204A and Wall A 206A, Column B 204B and Wall A 206A, Column B 204B and Wall B 206B, Column C 204C and Wall B 206B, Column C 204C and Wall C 206C, and Column D 204D and Wall C 206C. That is, Column A 204A is supported by slab 202, and Column A 204A in turn supports Wall A 206A, wall A 206A is supported by both Column A 204A and Column B 204B, and so on. Support relationships may or may not have a hierarchical order. For example, the support relationship between the slab 202 and the Column A 204A may be defined at a higher hierarchy level than the support relationship between the Column A 204A and Wall A. The hierarchical order can correlate or correspond to a workflow order. For example, building (or adjoining or supporting) of the construction elements with a support relationship at a higher hierarchical level may be completed, or required to be completed, before building (or adjoining or supporting) of the construction elements a support relationship at a lower hierarchical level.

The analysis of the data file, such as involving identification of construction elements, categorization of construction elements into shapes, determination of dimensions pertaining to the different shapes, calculation of values of the dimensions, performing of a mesh analysis, determining one or more support relationships between the construction elements, and/or construction of a support relationship network, can be implemented via one or more machine learning algorithms. For example, the identification of the construction elements, categorization of construction elements into shapes, determination of dimensions pertaining to the different shapes, calculation of values of the dimensions, determining one or more support relationships between the construction elements, and/or construction of a support relationship network, can be presented to a user for approval, modification, and/or correction. The approval, modification, correction, or other updates from the user can be stored in a database (or a plurality of databases) accessible by the server for use in the machine learning algorithms. Alternatively or in addition, the analysis of the data file can be performed automatically by the server (e.g., via one or more processors) without requiring human input or instructions.

Referring back to FIG. 1, after receipt 102 and analysis of the 3D model data file, the support relationships can be modified 104. The support relationships can be presented to a user for modification 104. For example, the user may manually add new support relationships between different construction elements or remove existing support relationships. In some instances, the user may group one or more such relationships, such as by orientation, by location, by type of support relationships (e.g., horizontal support, vertical support, base support, side support, etc.), and/or by construction elements (e.g., all support relationships involving a construction element in one group). In some instances, the user may re-arrange a hierarchical order of the support relationships in the network. For example, a user wishing for the construction work to flow from a Northern part of the building to a Southern part of the building can arrange the support relationship in a Northern part of the building to be defined before support relationships in a Southern part.

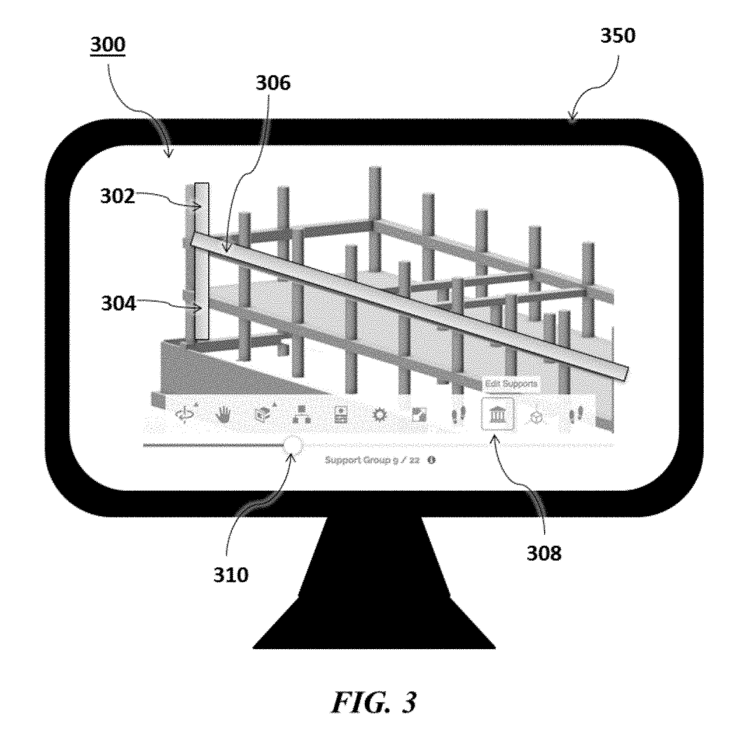

FIG. 3 illustrates a user interface for viewing and/or modifying support relationships. The support relationships may be presented to a user as a graphical representation, such as on a graphical user interface 300 on an electronic display 350. For example, the electronic display 350 can be communicatively coupled to a user device (e.g., computer, mobile phone, tablet, etc.) of the user. The graphical user interface 300 can be a dynamic user interface. In some instances, a support relationship can be presented one at a time, and the user may navigate between the respective graphical representations of the different individual support relationships by manipulating a user interactive object 310, such as a slider on a slider bar, to provide user input. As the user slides the object 310 on the slider bar, at different locations on the slider bar, different support relationships can be presented one at a time. Alternatively or in addition, a support relationship can be presented one group at a time, and the user may navigate between the respective graphical representations of the different groups by manipulating the user interactive object 310 to provide user input. As the user slides the object 310 on the slider bar, at different locations on the slider bar, different groups of support relationships can be presented one at a time. User interactive objects can include buttons, drop-down menus, text fields, sliders, or any other object that a user can provide input with and/or to.

In FIG. 3, a graphical user interface 300 shows a graphical representation of a support group #9 of 22 total support groups. The user may interact with the graphical representation on the graphical user interface 300, such as by zooming in, zooming out, rotating (e.g., yaw, pitch, roll directions, etc.) relative to a point (e.g., an arbitrary reference point the user selects, such as by clicking), moving (e.g., x, y, z directions, etc.) relative to a point, changing lighting, changing color scheme, and other methods of interaction. In the support group #9, a first column 302 of interest is supported by a second column 304 beneath the first column 302 and supported by a first beam 306 also beneath the first column 302. In some instances, each of the construction elements involved in the support relationships in the support group being presented on the graphical user interface 300 may be highlighted, such as by color, shade, bolding an outline of the shape, arrows, markers, symbols, blinking of the graphic of the construction element, dynamic effect, or other methods of emphasis. In some instances, a first construction element supported by a second construction element and the second construction element supporting the first construction element can be visually differentiated, such as by color, shade, bolding an outline of the shape, arrows, markers, symbols, blinking of the graphic of the construction element, dynamic effect, or other visual formats.

In some instances, each of the construction elements in the construction object may be a user interactive object, and the user may perform an action on or with a construction element, such as by selecting the construction element. The user may select (e.g., click, tap, touch, double-click, double-tap, tap and hold, etc.) the first column 302 of interest. Alternatively or in addition, the first column 302 of interest may be pre-selected by the server for the support group #9. The user may then select another user interactive object 308, such as a button, to modify support relationships of the first column 302. The user may, for example, add new support relationships of the first column 302 with other construction elements (e.g., with a second beam) and/or remove existing support relationships (e.g., with the second column 304 or the first beam 306) from construction elements supporting or supported by the first column 302. In some instances, the user may also re-arrange the support group #9 to be higher or lower in the hierarchy of 22 support groups in the 3D model of the construction object. In some instances, the user may re-arrange a support relationship within the support group #9 to be higher or lower in the hierarchy of the support relationships in the support group.

Referring back to FIG. 1, after modifying 104 support relationships between construction elements, the user may group 106 and split different construction elements. In some instances, the user may group and/or split different construction elements before or during either or both the aforementioned operations 102, 104. In some instances, the user may use a design tool (e.g., design software, application, platform, etc.), user-provided and/or server-provided, to achieve the splitting and/or grouping. For example, a large slab type construction element may be split into three smaller slab type construction elements. The splitting may be saved in the 3D model data file defining the construction object. In some instances, the splitting of one or more construction elements may modify the support relationships of the construction object. The server may re-evaluate the support relationships, such as by performing the operations 102, 104 previously described. Construction elements may be grouped together in any manner. For example, 1, 2, 3, 4, 5, 6, 7, 8, 9, 10, 20, 30, 40, 50, 100, 150, 200, 300, 400, 500, or more construction elements can be grouped together as one group. The construction elements grouped together may or may not share common features. A group may have a name or other identifier. In an example, a construction object may comprise a first sub-slab A and a second sub-slab B, each sub-slab supporting a plurality of columns thereon. A user may arbitrarily or categorically group together all columns on the first sub-slab A into a group named “columns on sub-slab A” and group together all column on the second sub-slab B into a group named “column on sub-slab B.” In some instances, the user may group together construction elements that the user intends to build as one group.

Next 108, the server may assign a construction recipe for each construction element. The server may access a construction recipe library stored in one or more databases and/or memory that may be local or external to the server. The construction recipe library can comprise one or more recipes, each recipe in the library comprising a formula for building a specific type of construction element. The server may assign an existing recipe saved in the construction recipe library for a construction element. Alternatively or in addition, a new recipe can be created and saved in the construction recipe library to assign to a new type of construction element. A recipe can be constrained by available resources, such as in a resource pool which is described further below.

The same recipe can be used for the same type of construction element. For example, the same recipe can be used for all beams. In some instances, different recipes may exist for the same type of construction element. For example, different recipes may exist for the same type of construction element having different parameters (e.g., dimension, material, placement, location, orientation, etc.) or having different sub-types. As an example, different recipes can exist for I-beams (e.g., H-Beam, W-beam, etc.) and curved beams. As another example, different recipes can exist for I-beams having a length dimension less than x₁, I-beams having a length dimension in the x₁-x₂ range, I-beams having a length dimension in the x₂-x₃ range, and I-beams having a length dimension greater than x₂. As another example, different recipes can exist for I-Beams having different width:length dimension ratios.

A recipe may be assigned to a construction element with user input, such as with user instructions to assign the recipe to the construction element. Alternatively or in addition, a recipe may be assigned to a construction element automatically (e.g., by a computer algorithm) without user input. For example, the server may assign a recipe based on the shape and/or type of the construction element. Where there are multiple different recipes for the same type of construction element in the construction recipe library, the server may select a recipe based on context of the construction element extracted from the data file, such as a location, orientation, or support relationship. Alternatively or in addition, the server may select a recipe using a machine learning algorithm, such as based on past user preference. Alternatively or in addition, a predetermined default recipe (e.g., pre-programmed) may be selected by default. In some instances, a user may override automatic selection or assignment of a recipe to a construction element by the server.

For example, there may be one recipe each for a slab type construction element, a column type construction element, a wall type construction element, and a beam type construction element. A same slab recipe may be applied to all slab type construction elements, a same column recipe may be applied to all column type construction elements, a same wall recipe may be applied to all wall type construction elements, and a same beam recipe may be applied to all beam type construction elements. Beneficially, where there is a plurality of the same type of construction element, the same construction recipe can be applied to each of the same type of construction element without having to manually (and redundantly) create and manually logically relate different operations for each construction element. This can significantly save both user-required labor (e.g., defining operations) as well as memory and processing capacity of the computer server (e.g., server) facilitating the construction planning. Furthermore, the probability of introducing error (e.g., user error, system error) is also reduced. For example, referring back to the construction object 200 in FIG. 2A which has 19 construction elements including 1 slab, 12 columns, and 6 walls, only three total construction recipes can be required, a slab recipe for the 1 slab, a column recipe for the 12 columns, and a wall recipe for the 6 walls. If 5 operations were required to build each construction element, this would reduce 95 operations (5 for each of 19 construction elements) to be defined to 15 operations (5 for each of 3 construction recipes) total operations.

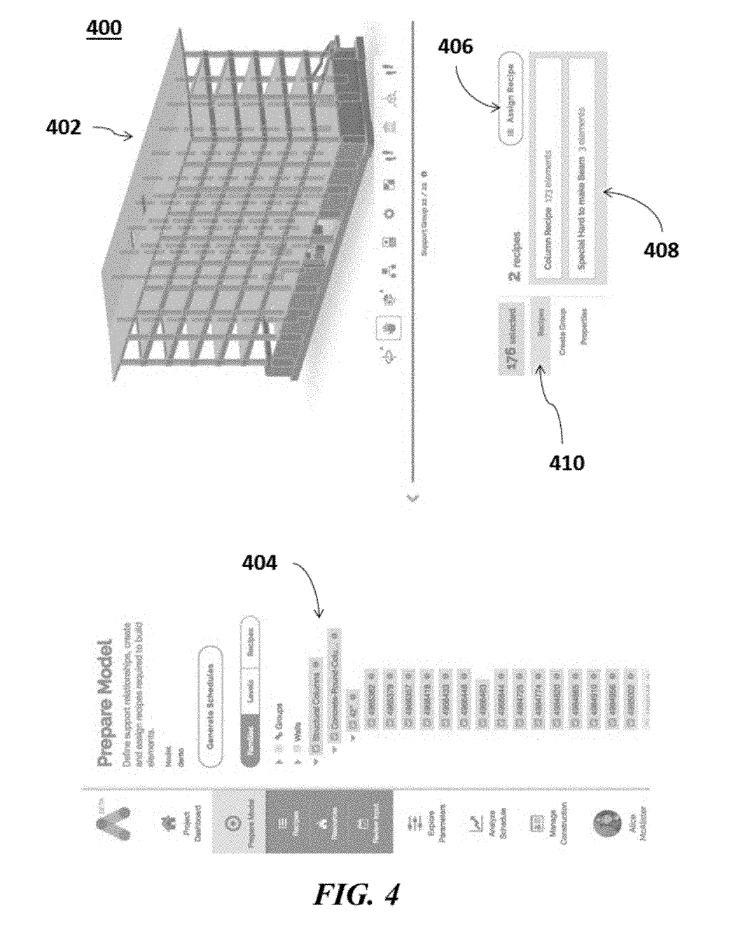

FIG. 4 illustrates a user interface for assigning construction recipes to construction elements in a construction object. A graphical user interface 400 can be presented to a user on an electronic display (not shown). The graphical user interface 400 can be a dynamic user interface. In some instances, the graphical user interface 400 can show a navigation panel 404, such as a tree view navigation panel, of the different construction elements in the construction object. The navigation panel 404 can show groups of construction elements and/or individual construction elements, such as in a nodal structure. The individual construction elements and/or groups thereof can be identified a name or other unique identifier (e.g., text, graphic, symbol, etc.). Each construction element in the navigation panel 404 can be selectable (e.g., via clicking, tapping, etc.). In some instances, the graphical user interface 400 can show a graphical representation 402 of the 3D model of the construction object and/or the construction elements. In some instances, the graphical representation 402 can be the graphical representation of the support relationships in FIG. 3. Each construction element in the graphical representation 402 can be selectable. In some instances, selection of a construction element in either the navigation panel 404 or the graphical representation 402 can automate selection in the other. A selected construction element can be emphasized, such as via bolding, color, shading, blinking or other dynamic effect, and/or other methods of emphasis described elsewhere herein.

For example, in FIG. 4, a user may select a plurality of columns from the navigation panel 404. The user may then select a recipe menu 410 (e.g., button, link, etc.) from a user menu, and select an assign recipe option 406 (e.g., button, link, etc.) to select a construction recipe from the construction recipe library to assign to the selected plurality of columns. Alternatively or in addition, the user may create a new recipe to assign to the selected plurality of columns. The selection can be presented in a selection display 408.

A recipe can be created and/or defined by a user. For example, the user may provide one or more operations, sequence thereof, one or more resources, production rate, spatial requirements, temporal requirements, and/or other instructions or factors in the formula of the recipe. A recipe can be pre-defined in the server, such as for reference as a template. A recipe can be defined by both server and user input. For example, a user may modify a pre-defined template recipe for a construction element. In another example, the server may automatically complete, or recommend suggestions (e.g., auto-complete suggestions) to, a user-defined recipe.

A recipe in the library can comprise a formula for building a specific type of construction element. The formula in a recipe can define one or more operations (e.g., place formwork, place steel, pour concrete, dry concrete, remove formwork, etc.) and sequence or interconnections thereof for building the construction element. The formula can define logical relationships between the operations. An operation can define one or more resources (e.g., raw material, labor, etc.), production rate, spatial requirements, temporal requirements, and/or other instructions or factors for the operation. The formula may be dependent on one or more parameters (e.g., material, dimensions, etc.) of the specific type of construction element.

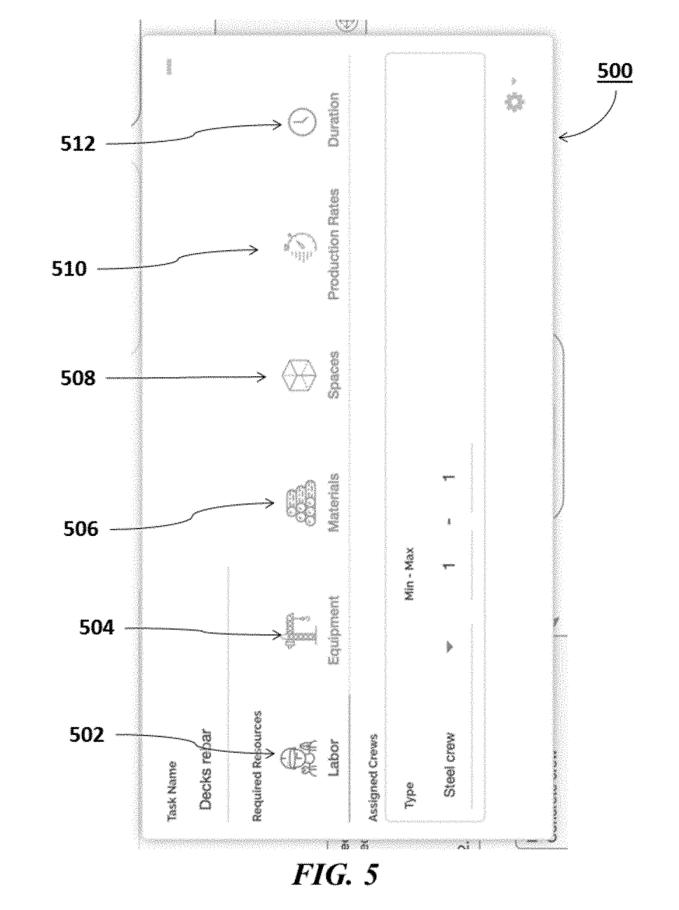

To create a recipe for a construction element, one or more operations, or processes, required to build the construction element is created. The operation can be identified by a name or other identifier. The name or other identifier can be provided by the user and/or the server. FIG. 5 illustrates a user interface for creating an operation in a recipe. A graphical user interface 500 is shown on an electronic display (not shown). The graphical user interface 500 can be a dynamic user interface. Each operation defines required resources (e.g., labor 502, equipment 504, material 506, space 508, etc.), duration 512, and production rates 510. An operation can define other factors or instructions for building a construction element. The definitions can be in numerical format, text string format, visual instructions (e.g., modeling a safety area for space 508), and/or other instruction formats.

In some instances, duration 512 can be calculating using the production rate 510 and dimension values previously calculated for the construction element. For example, duration can be equal to a construction element volume divided by the production rate (where production rate is defined in volume unit per time unit). In another example, duration can be equal to a different construction element dimension (e.g., length, width, etc.) divided by the production rate (where production is defined by the corresponding dimension per time unit). Alternatively or in addition, duration can be manually fixed to a user defined value (e.g., 4 days).

For an operation, the required resources can be defined. In some instances, available resources can be separately defined in the resource pool which is described further below. For labor 502, a minimum and/or maximum number of assignable crews can be provided. Alternatively or in addition, a minimum and/or maximum number of assignable workers can be provided. For example, a minimum of 1 steel crew and a maximum of 3 steel crews can be provided for an operation. Beneficially, during actual construction, when free steel crews are available at some point, the free steel crews can be assigned to operations having extra capacity in the minimum-maximum range. Thus, flexibility is built into the operation definition.

For equipment 504, constraints for the equipment can be provided. For example, for a crane, a location of the crane, radius, and time required to move between locations can be provided. In some instances, a specific model of an equipment can be selected, and radius can be automatically provided by the program. The server may determine, based on the information provided, all the elements that the equipment is capable (or incapable) of reaching. Beneficially, especially because construction equipment can be costly, limited, and difficult to maneuver, the constraints can ensure, ahead of time, that the equipment is distributed where necessary and where it is capable of operating.

For material 506, a type and amount of materials can be provided. For example, a material can be selected to be reusable (e.g., formwork) or consumable (e.g., bricks). In some instances, some resources may have a limited number of reusable lives (which can be defined in the operation or in the resource pool), such as to define formwork to be reusable a maximum of 5 times after which it may be too damaged for re-use.

For space 508, an area and location for the space can be provided. For example, a user and/or the server can set areas to be blocked off around the operation being performed. Beneficially, work paths and safety areas can be built into the operation.

For production rates 510, rates for the operation can be provided. For example, a rate of pouring concrete, a rate of removing formwork, and other rates can be provided. Beneficially, production rates provided for one operation can also be used for another operation. For example, production rates can be saved as a global variable accessible from all operations and/or all recipes in the system. For instance, the rate of pouring concrete can be used for both an operation in a column recipe and an operation in a slab recipe.

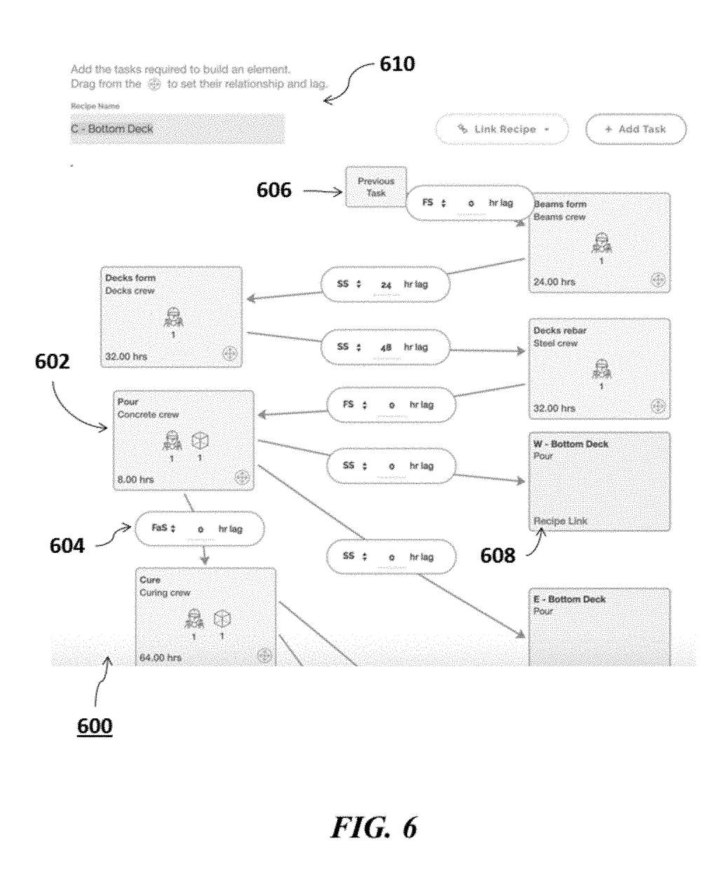

The plurality of operations in a recipe may or may not be interlinked via one or more logical inter-operation relationships. FIG. 6 illustrates a user interface for creating a recipe. A graphical representation of a recipe 610 is shown on a graphical user interface 600 on an electronic display (not shown). The graphical user interface 600 can be a dynamic user interface. The recipe can comprise one or more operations (e.g., operation 602) and one or more logical relationships (e.g., relationship 604) interconnecting the one or more operations. In some instances, a recipe having one operation may not have any logical relationships.

A logical relationship can be a task dependency. For example, a logical relationship can be a Finish-to-Start (FS) type relationship. A FS relationship from operation A to operation B can mean that operation A must finish before operation B can start. Operation B can start any time on or after operation A is finished, for example, immediately after operation A finishes (e.g., 0 time lag) or after a time lag. The time lag can be defined, such as in units of seconds, minutes, hours, days, weeks, months, years, or other time units. The relationship can be closed or open. In an open relationship, for example, Operation B can start any time after an x time lag (x≥0). In a closed relationship, for example, Operation B can start exactly, or substantially precisely within a certain tolerance (e.g., about 1%, 2%, 3%, 4%, etc.), after x time lag. For example, a closed FS relationship from a cement curing operation to a painting operation with a 1 hour time lag can mean that the painting operation starts precisely 1 hour after the cement curing operation is completed or within a certain tolerance of the 1 hour time lag. In another example, an open FS relationship from a cement curing operation to a painting operation with a 1 hour time lag can mean that the painting operation can start any time at or after 1 hour after the cement curing operation is completed.

A logical relationship can be a Start-to-Start (SS) type relationship. A SS relationship from operation A to operation B can mean that operation A must start before operation B can start. Operation B can start any time on or after operation A starts, for example, immediately after operation A starts (e.g., 0 time lag, start substantially in parallel) or after a time lag. The relationship can be closed or open. For example, a closed SS relationship from a cement pouring operation to a heating operation with a 1 hour time lag can mean that the heating operation starts precisely 1 hour after the cement pouring operation starts. In another example, an open FS relationship from a cement pouring operation to a heating operation with a 1 hour time lag can mean that the heating operation can start any time at or after 1 hour after the cement pouring operation has started.

A logical relationship can be a Finish-to-Finish (FF) type relationship. A FF relationship from operation A to operation B can mean that operation A must finish before operation B can finish. Operation B can finish any time on or after operation A finishes, for example, immediately after operation A finishes (e.g., 0 time lag, finish substantially in parallel) or after a time lag. The relationship can be closed or open. For example, a closed FF relationship from a molding operation to a curing operation with a 1 hour time lag can mean that the curing operation finishes precisely 1 hour after the molding operation finishes. In another example, an open FF relationship from a molding operation to a curing operation with a 1 hour time lag can mean that the curing operation can finish any time at or after 1 hour after the molding operation has finished.

A logical relationship can be a Start-to-Finish (SF) type relationship. A SF relationship from operation A to operation B can mean that operation A must start before operation B can finish. Operation B can finish any time on or after operation A starts, for example, immediately after A starts (e.g., 0 time lag) or after a time lag. The relationship can be closed or open. For example, a closed SF relationship from a molding operation to a curing operation with a 1 hour time lag can mean that the curing operation finishes precisely 1 hour after the molding operation starts. In another example, an open SF relationship from a molding operation to a curing operation with a 1 hour time lag can mean that the curing operation can finish any time at or after 1 hour after the molding operation has started.

A logical relationship can also be a Finish-at-Start (FaS) type relationship. A FaS relationship from operation A to operation B can mean that operation B must start immediately upon operation A finishing. For example, a FaS relationship from a pouring concrete operation to a curing concrete operation can mean that the curing concrete operation is started immediately after the pouring concrete operation is complete. In another example, while a FS relationship from operation A to operation B with 0 time lag permits operation B to start any time after operation A is finished, a FaS relationship from operation A to operation B requires operation B to start immediately upon operation A finishing.

Any two operations in a construction recipe can be related via a logical relationship, such as by joining the two operations with a type of logical relationship (e.g., FS, SS, FF, SF, FaS, etc.) on the graphical interface 600. An operation can be related to a plurality of other operations via separate logical relationships. For example, an operation can be related to three other operations via three separate logical relationships. In some instances, an operation in a first recipe can be related via a logical relationship to another operation in a second recipe. For example, an operation can be linked from a previous recipe via a previous task link 606 and linked to a subsequent recipe via a next task link (not shown in FIG. 6). A previous task link in a first recipe can be linked to a next task link in a second recipe via a recipe relationship. In another example, an operation can be linked to a different recipe via an external recipe link 608.

Referring back to FIG. 1, after creating and/or assigning 108 a recipe to the construction elements, recipe relationships between the recipes can be created 112. The plurality of recipes in the construction recipe library for the construction object may or may not be interlinked via one or more recipe relationships. For example, a first recipe can be linked to a second recipe via a recipe relationship (e.g., previous task-next task link, external recipe link, etc.). A recipe can be linked to a plurality of recipes. In some instances, a single recipe relationship can define a one-to-one relationship between two recipes. In other instances, a single recipe relationship can define a relationship between more than two recipes, such as a one-to-many relationship, many-to-one relationship, many-to-many relationship, and/or a plurality of one-to-one relationships. A recipe relationship can be a logical constraint. The recipe relationship can define a sequential relationship, such as to identify which recipe is to be performed first, which recipe is to be performed after, which recipes are to be performed in parallel, which recipe is to be performed at a particular time (e.g., 45 minutes time lag, etc.), step, operation, phase, stage, point, duration, and/or other unit relative to another recipe, and other sequential relationships. A recipe relationship can be a task dependency relationship (e.g., FS, SF, SS, FF, FaS, etc.) as described elsewhere herein. A recipe relationship can link a recipe to external recipes (e.g., such as via an external recipe link 608), such as for building at another location. In some instances, a recipe relationship between recipes of different construction elements can be based on the support relationships of the different construction elements identified earlier. For example, a recipe relationship can be constrained by a support relationship.

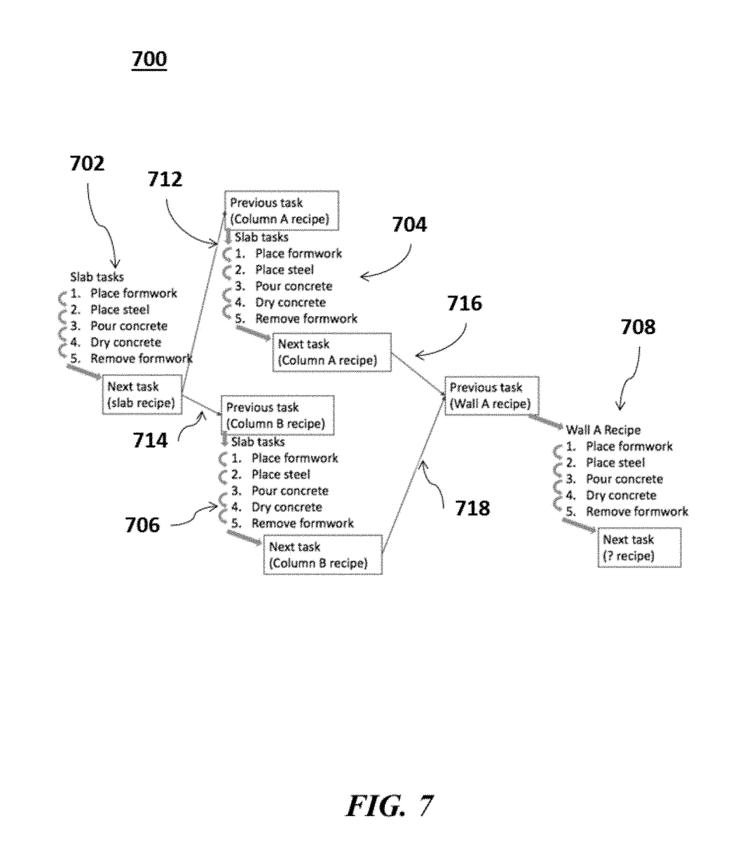

FIG. 7 illustrates a network of recipe relationships. A network 700 can show both intra-recipe (e.g., inter-operation) relationships and inter-recipes relationships. The network 700 can have a first slab recipe 702, a column A recipe 704, a column B recipe 706, and a wall A recipe 708. Each recipe can be defined by one or more operations. For example, the first slab recipe 702 is defined by a first operation to “place formwork,” a second operation to “place steel,” a third operation to “pour concrete,” a fourth operation to “dry concrete,” and a fifth operation to “remove formwork.” The operations in each recipe may be logically related by one or more logical relationships (e.g., intra-recipe, inter-operation, etc.), such as described with reference to FIG. 6.

A plurality of recipes can be logically related by one or more recipe relationships (e.g., inter-recipes relationship). For example, the four recipes 702, 704, 706, 708 can be interlinked via a first recipe relationship 712, second recipe relationship 714, third recipe relationship 716, and a fourth recipe relationship 718. Any operation in a recipe, regardless of sequence or order of such operation in the recipe, for example, can be linked to any other operation in a different recipe. In some instances, the inter-recipes relationship can be a support relationship between construction elements (e.g., discussed with respect to FIGS. 2A and 2B). An operation can be linked to a plurality of operations, such as in a plurality of different recipes. For example, as shown in FIG. 7, a ‘remove formwork’ operation in the first slab recipe 702 can be linked to a ‘place formwork’ operation in the second slab recipe 704 and a ‘place formwork’ operation in the third slab recipe 706. While FIG. 7 shows the last operation of a recipe linked to the first operation of another recipe, any operation can be linked to different recipes. For example, an intermediary ‘pour concrete’ operation in the first slab recipe 702 may be linked to an intermediary ‘place steel’ operation in the second slab recipe 704. That is, each operation in a recipe can be an entry point from another recipe to the recipe. Each operation in a recipe can be an exit point from the recipe to another recipe. An operation can be both an entry point and an exit point. There may be multiple entry and/or exit points in a recipe.

An operation in a recipe may be linked to another operation external to the recipe via previous task and next task links. For example, a ‘remove formwork’ operation in the first slab recipe 702 can be linked to a next task link in the first slab recipe 702. The next task link in the first slab recipe 702 can link to the respective previous task links of two separate recipes, the column A recipe 704 and the column B recipe 706, via the first recipe relationship 712 and the second recipe relationship 714, respectively. The previous task link for the column A recipe 704 can be linked to a ‘place formwork’ operation in the column A recipe 704. The previous task link for the column B recipe 706 can be linked to a ‘place formwork’ operation in the column B recipe 706. For example, after completing the ‘remove formwork’ operation in the first slab recipe 702, the ‘place formwork’ operations in each of the column A recipe 704 and the column B recipe 706 can start. The task dependency of the ‘place formwork’ operation in the column A recipe 704 to the ‘remove formwork’ operation in the first slab recipe 702 can be defined by the first recipe relationship 712 (e.g., FS, SS, SF, FF, FaS, etc.). Alternatively or in addition, the task dependency between operations in different recipes can be defined by a logical relationship from an operation to a next task link and/or a logical relationship from a previous task link to an operation. The column A recipe 704 and the column B recipe 706 can each be linked to the wall A recipe 708 via the third recipe relationship 716 and the fourth recipe relationship 718, respectively. The recipe relationship between a previous recipe and a subsequent recipe can be linked via a previous task link in the subsequent recipe and a next task link in the previous recipe. The recipe relationship between a previous recipe and a subsequent recipe can be linked via an external recipe link.

Thus, logical relationships (or constraints) can be created and managed both intra-recipe (e.g., inter-operation) and inter-recipes. Beneficially, different construction operations for a construction object can be managed within a construction element and between construction elements.

Referring back to FIG. 1, while creating and/or assigning 108 a recipe for the construction elements, a resource pool for the construction project can be defined 110. The systems and methods may provide a resource pool for a construction project. The resource pool can define the available resources for the construction project, such as labor (e.g., skill set in labor pool, standard work week, available dates, cost, etc.), equipment (e.g., location, reach, available time, efficiency, cost, etc.), materials (e.g., amount, type, cost, etc.), space (e.g., area, volume, height, equipment allowed in space, available time, labor allowed in space (e.g., maximum number of adults), cost, etc.), production rates (e.g., rates at which operations are carried out, etc.), work weeks (e.g., hours a week per crew, hours a week per individual, etc.), and other resources. Some resources, such as space and production rates can be global variables that are accessible from any recipe in the construction recipe library. A recipe may draw resources from the resource pool. For example, the resource pool can present a constraint on the recipe or assignment of a recipe. In another example, the resource pool can present a constraint on one or more logical relationships between operations and/or between recipes (e.g., a SS relationship between two operations with 0 time lag may not be possible if resources available in the resource pool are insufficient, but a FS relationship may be possible).

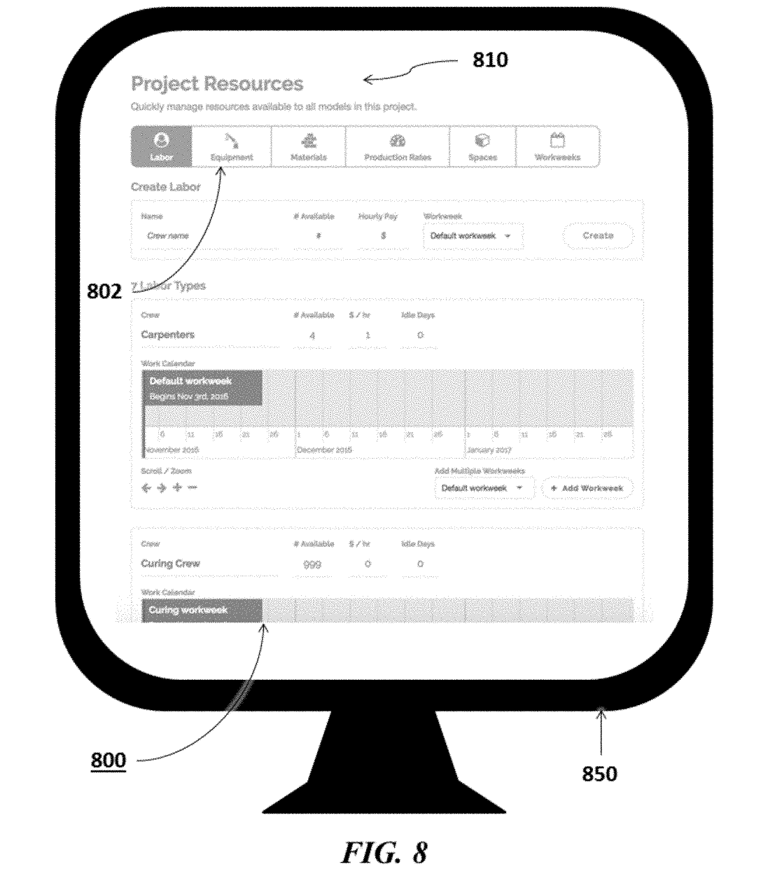

FIG. 8 illustrates a user interface for defining a resource pool for a construction project. A graphical representation of a resource pool 810 is shown on a graphical user interface 800 on an electronic display 850. The graphical user interface 800 can be a dynamic user interface. The resource pool can comprise definition of one or more resources. The graphical representation of the resource pool 810 can have a resource navigation panel 802, such as to navigate between the different types of resources (e.g., labor, equipment, materials, production rates, spaces, workweeks, etc.). FIG. 8 illustrates a labor view of the resource pool.

For the labor resource, factors such as types of crews (e.g., carpenters, curing crew, etc.), number of workers per crew, wage (e.g., hourly pay, weekly pay, monthly pay, annual pay, per operation pay, per construction element pay, per construction project pay, etc.), idle days, and workweeks for the crew can be defined. For the equipment resource, types of equipment (e.g., cranes), flexibility of equipment (e.g., fixed in location, movable between different locations), available locations, reach, time required to move between locations, travel speed, and other equipment properties can be defined. For the material resource, factors, such as the amount and type (e.g., consumable, reusable, etc.) of material can be defined. In some instances, dimensions of material units can be defined. In some instances, the number of reusable cycles for a material unit can be defined. In some instances, the type of material can be specific (e.g., brick Brand A, brick Brand B, etc.) For the production rates resource, rates at which different operations are performed can be defined. For the space resource, a set of one or more spaces can be created by the construction elements involved in an operation. For the workweeks resource, definitions of times that a crew or a worker works can be defined. For example, a workweek can define how many hours a week a crew works. Such workweeks can be combined together, such as to create partial or complete calendars of workweeks. One or more resources in the resource pool, such as the production rates and the space, can be global variables that when created once can be used (or shared) by multiple recipes.

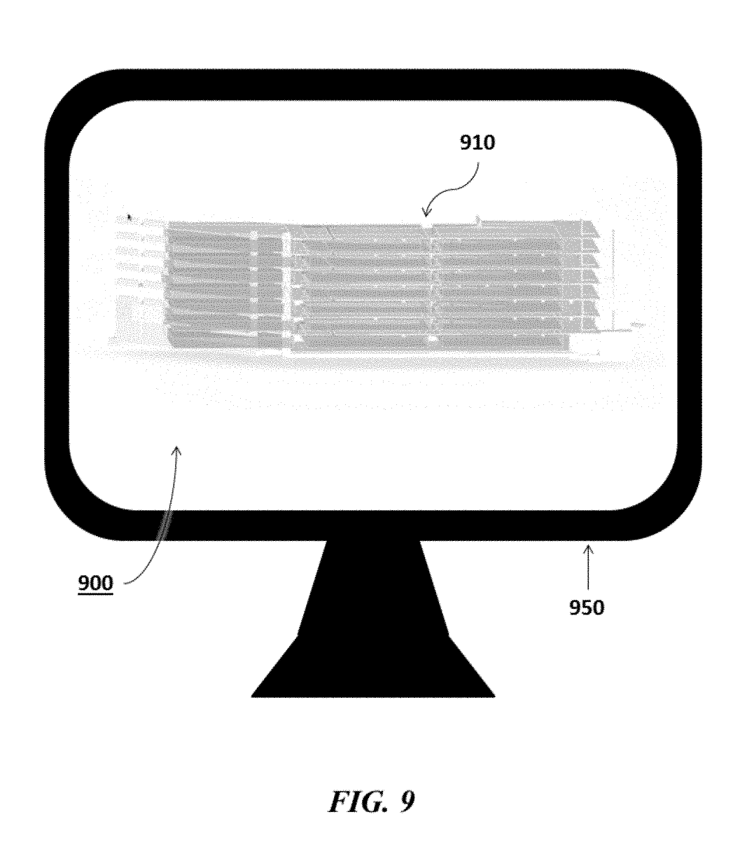

FIG. 9 illustrates a user interface for defining a space in a resource pool. A graphical representation of a space 910 is shown on a graphical user interface 900 on an electronic display 950. The graphical user interface 900 can be a dynamic user interface. The space can accommodate one or more construction elements. A user may select one or more construction elements and then drag (or otherwise interact with the construction elements or computer objects representing the construction elements) the one or more construction elements onto a space editing platform to create a space and/or a set of spaces. The set of spaces created by the user can be saved as global variables in the resource pool. Beneficially, the set of spaces can be accessed and/or shared by multiple recipes without requiring users to build the same space multiple times with small variations that can overlap and present problems during consolidation of the construction plan.

The systems and methods may provide comprehensive construction planning for a construction project using the abovementioned tools, such as construction recipes, recipe relationships, and/or the resource pool. Beneficially, logical relationships can be created and managed both intra-recipe (e.g., inter-operation) and inter-recipes to achieve both detailed and high level planning for a construction project. The intra-recipe relationships and inter-recipe relationships can be constrained by inter-connected logical relationships and the available resources in the resource pool such that changes can be made at any level of detail, including within an element, within a recipe, within the whole project, or any other level, without cyclic definitions. In some instances, one or more logical relationships may be created between groups of recipes. A logical relationship between groups of recipes may be created at different levels of detail, allowing for flexible control of hierarchies of recipes.

The construction planning and/or scheduling can be modified or updated in real-time, such as by modifying or updating one or more parameters (e.g., operation, element, grouping, recipe, etc.) of the construction plan. Upon modification or update, the construction project can be re-planned and/or re-scheduled. The parameters that can be modified or updated can include parameters, such as parameters of available resources in the resource pool and/or properties (e.g., amount, type, cost, etc.) thereof, sequence parameters, and parameters of the construction method (e.g., recipe, recipe relationship, support relationship, etc.) and/or properties thereof

As an example, a modification in the number of available resources can modify the number of available resources in the resource pool and reduce or extend a duration of completion for an operation, a recipe, and/or the whole project. In another example, requiring the finish of an operation, recipe, and/or the project within a fixed duration with reduced resources can require overtime work for available labor and increase costs. A sequence parameter can be modified, such as a hierarchical order in support relationships, a sequence of operations in a recipe, and/or a sequence of recipes in the construction project. In some instances, logical relationships can be modified, which can in turn affect sequence. In some instances, support relationships between construction elements can be modified, which can in turn affect sequence. A construction method parameter can be modified, such as a recipe definition, an operation definition within a recipe, logical relationships between operations in an recipe, logical relationships between operations in different recipes, logical relationships between different recipes, and/or other construction method parameter. As an example, a construction recipe can modified such that a paint operation is added, or a drying time of concrete is reduced from 72 hours to 24 hours. A duration parameter, such as in a recipe, can be modified. A production rate parameter, such as in the resource pool and/or a recipe can be modified. An equipment parameter, such as crane type (e.g., no movement, movement) or a duration to move the crane between different locations can be modified. Any other parameter can be modified. Modifying, creating, deleting, or updating a parameter (e.g., modifying a recipe) can automatically update other parameters and/or variables throughout the construction plan for the whole construction project, such as to ensure there are no conflicts within the plan and the changes are feasible. The parameters and/or variables throughout the construction plan may be integrated in the construction plan such as to prevent cyclic definitions. In some instances, when the changes in a parameter conflicts with another parameter or are not feasible, the server may provide an error or warning message to the user. In some instances, a user may override the error or warning message and force the change.

Referring back to FIG. 1, the construction plan can be scheduled 114. For example, at least one part of the construction plan, such as an operation, can be plotted on a timeline. During scheduling, a start time and/or end time can be assigned to at least one part of the construction plan (e.g., operation). In some instances, a start time and/or end time can be assigned for the whole construction plan. In some instances, a start time and/or end time can be assigned for a part of the construction plan. The remaining part may or may not be automatically scheduled based on the first scheduling input. In some instances, the construction plan and schedule thereof can be visualized 116 on a graphical user interface. For example, the construction plan can be visualized as a list of operations that need to be completed, their respective durations, their respective required resources, and other definitions. The plan and/or schedule can be visualized as a plot, graph, table, or other charts showing information such as cost and duration (e.g., as axes in a graph, columns in a table, etc.). In another example, the plan and/or schedule can be visualized as a three-dimensional (3D) visual output showing a time-dependent 2D cross-sectional output progress. In another example, the plan and/or schedule can be visualized as a four-dimensional (4D) visual output showing a time-dependent 3D output progress, such as a 4D Gantt chart. The visualization may be filtered by different factors, resources, and/or other parameters. The construction plan and schedule can be presented on a dynamic user interface, such as having one or more user interactive objects (e.g., slider bar). In some instances, the construction plan and schedule can be visualized as information cards, such as by time, crew, operation, and/or construction element.

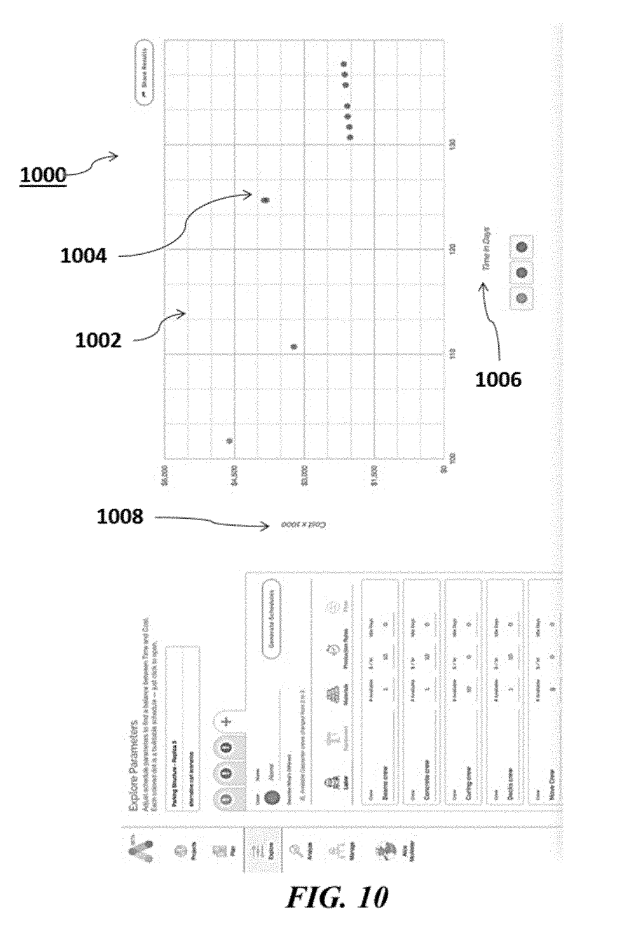

FIG. 10 illustrates a user interface for presenting a visualization of parametric scheduling. A graphical representation of parametric scheduling is shown on a graphical user interface 1000 on an electronic display (not shown). The graphical user interface 1000 can be a dynamic user interface. The outcome of a schedule for each modification or variation in parameter can be plotted in a chart 1002. For example, the chart 1002 can have two axes, including a duration (or time) axis 1006 and a cost axis 1008. Alternatively or in addition, the output can be represented in other forms of visualization methods, such as tables, graphs, charts, plots, or other forms of graphical representation. Alternatively or in addition, the output can be plotted as a function of a different combination of variables, such as duration, cost, total labor, efficiency, rate, and/or other variable. Each point (e.g., point 1004) can represent a construction plan and corresponding construction schedule with different parameters. In some instances, the location of a point on the chart 1002 for a construction plan and/or schedule can be indicative of a duration and total cost of the project. Beneficially, such visual plotting can easily allow assessment of whether a construction plan is within an operable or objective time frame and/or operable or objective cost. Different construction plans and/or schedules may be easily compared. This can help with downstream planning, downstream scheduling, and/or even downstream financing. In some instances, each point can be a user interactive object that can be selected. Upon selection of a point, more detailed information can be provided on the construction plan and/or schedule represented by the point. Such detailed information may be visualized, such as in the form of a 4D model and/or an enhanced Gantt chart.

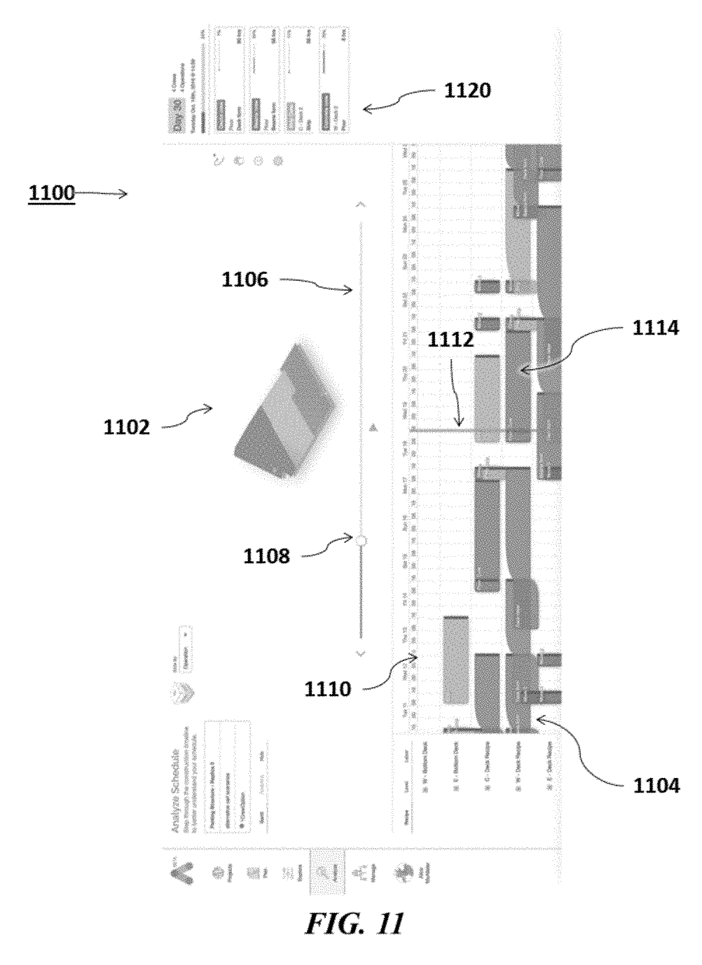

FIG. 11 illustrates a user interface for presenting an enhanced Gantt chart for an exemplary construction schedule. One or more graphical representations of a construction schedule are shown on a graphical user interface 1100 on an electronic display (not shown). The graphical user interface 1100 can be a dynamic user interface.

A construction schedule having a particular set of parameters (e.g., such as represented by data point 1004 in FIG. 10) can be visualized as a 4D model 1102. The 4D model 1102 can be a 3D model of the construction object varying along a time axis 1106. A progress of the construction schedule may be visualized by presenting an expected (or actual) status of the construction object as a 3D model at a time of interest 1108 on the time axis 1006. The time of interest 1108 can be changed, such as by manipulating a user interactive slider along the time axis 1006. For example, depending on the location of the slider, the 3D model can be updated for view. In some instances, the 4D model can be viewed in playback, along a segment (e.g., start to finish segment, intermediate segment, etc.) of the time axis 1006, such as by selecting a ‘play’ button.

Alternatively or in addition, the construction schedule can be visualized as an enhanced Gantt chart 1104. The enhanced Gantt chart 1104 can have a time axis 1112. The time axis 1006 of the 4D model 1102 and the time axis 1112 of the enhanced Gantt chart 1104 can be correlated to each other. For example, the time location of the time of interest 1108 on the time axis 1106 can correspond to the time location of the vertical slider 1112 on the time axis 1110.

The enhanced Gantt chart 1104 can comprise a plurality of bars (e.g., bar 1114). A bar can represent an operation a crew must perform. The bars can be organized in rows, such as by operations in a recipe, operations in a location (e.g., level of a building), and/or operation by type of labor. For example, all operations in a single recipe can be visualized along the same row, and each row can represent a different recipe. In another example, all operations in a single location (e.g., C-deck, W-deck, E-deck, etc.) can be visualized along the same row, and each row can represent a different location. A bar can be labeled with an identifier of the operation, such as an operation name (e.g., “pour,” “cure,” “paint,” etc.).

In some instances, the bars can be color coded, such as by crew type (e.g., carpenters, painters, etc.). The bars can be color coded by other characteristics of an operation (e.g., duration, equipment, material, etc.). Alternatively or in addition, the bars can be visually grouped or categorized via another method (e.g., stripes, patterns, dynamic effect, shape, thickness of bar, etc.). The color coding or other visual marker of the bars in the enhanced Gantt chart 1104 can be correlated to the 4D model 1102, such that the respective colors of the construction elements in the 3D model corresponds to the color or other visual marker of the operation involving the construction elements. If more than one operation involves the construction element at the time of interest 1108 (e.g., corresponding to vertical slider 1112), the colors or other visual marker of the operations can be combined, such as in a stripe pattern or other forms of combination (e.g., blend of colors, other patterns, border and filling, etc.).

A bar may curve up at the end, such that operations taking a longer duration are more distinguished and easier to follow visually. For example, two bars overlapping, partially or completely, on the time axis 1110 can be distinguished in the overlapping portions by their respective curvatures or lack thereof. Advantageously, more bars, and thus more information, can be fit into a single chart without clustering the chart or adversely affecting legibility of the chart. The end of an operation can be represented by a black vertical bar at the end (e.g., right end). Alternatively or in addition, the end of an operation can be represented or otherwise emphasized by other visual markers (e.g., symbols, markers, different colors, different patterns, etc.). In some instances, the start of an operation can be represented or otherwise emphasized by visual markers. In some instances, a key reference time point (e.g., midpoint, 25%, 75%, 24 hours, 36 hours, 72 hours, etc.) in an operation can be represented or otherwise emphasized by visual markers.

When similar operations are performed by multiple crews of the same type, the similar operations may be collapsed as one bar, but the bar being identified with identifiers, such as operation names, of each of the operations collapsed into the one bar. Beneficially, this can avoid clustering the enhanced Gantt chart 1104 and make the chart easier to read.

The enhanced Gantt chart 1104 may be filtered, such as by crew type, recipe, element type, locations, and other groups described elsewhere herein. Beneficially, such filtered Gantt charts can be customized for users participating or interested in a particular type of group. For example, a particular crew may be provided with a Gantt chart of only the operations the crew is involved in. Such Gantt charts can be distributed daily, weekly, monthly, or for any time duration within or beyond the construction project duration.

A slider to navigate through the time axis 1106 for the 4D model 1102, such as to select the time of interest 1108, may move forward or backward through the time axis 1106 in variable increments. The time axis 1106 can be a discrete or continuous axis. For example, the slider can move in discrete increments of time, such as in increments of seconds, minutes, hours, days, weeks, months, quarters, years, or other time increments. Alternatively or in addition, the slider can move in discrete physical increments, such as in increments of operations, elements, recipes, crews, locations, or other groups. Alternatively or in addition, the slider can move continuously along the continuous axis as allowed by the resolution of the graphics on the graphical user interface 1100. The vertical slider 1112 to navigate through the time axis 1110 for the enhanced Gantt chart 1104 may move forward or backward through the time axis 1110 in variable increments, such as in discrete time increments and/or discrete physical increments, as described above. The vertical slider 1112 can move continuously along the continuous axis as allowed by the resolution of the graphics on the graphical user interface 1100.

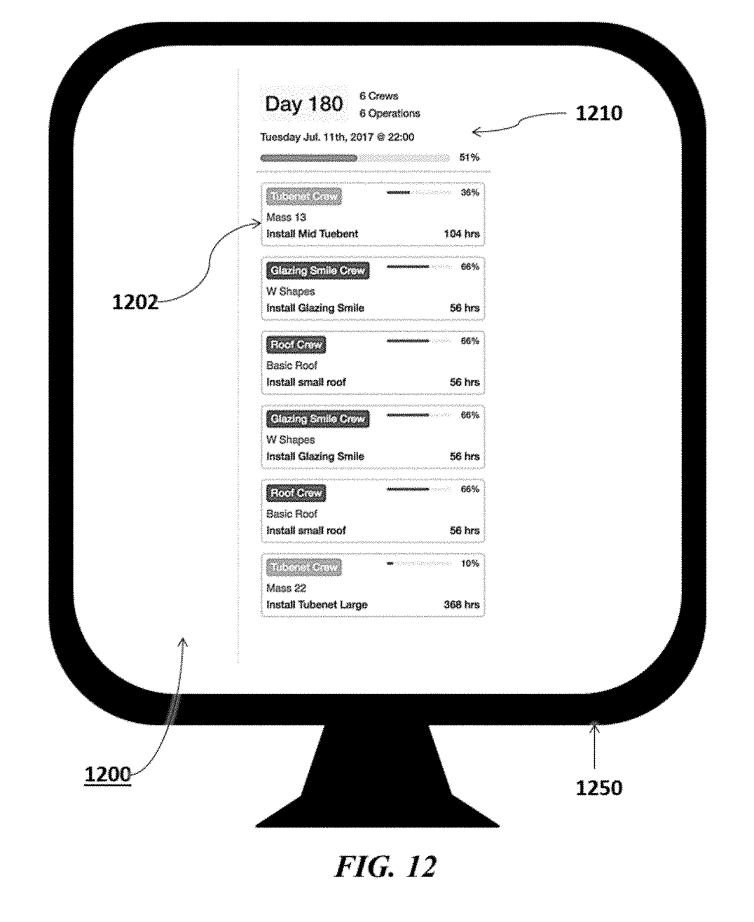

In some instances, the construction planning and/or scheduling can be visualized as information cards 1120. FIG. 12 illustrates an enlarged view of the information cards of FIG. 11. A plurality of information cards (e.g., information card 1202) are shown on a graphical user interface 1200 on an electronic display 1250. The graphical user interface 1200 can be a dynamic user interface. The information cards can display information about the progress of a construction project at a segment of time, such as at a particular hour at a particular date (e.g., Tuesday Jul. 11, 2017 at 22:00). The information cards can display information at any time. Referring back to FIG. 11, the segment of time pertaining to the information cards 1120 can correspond to the time of interest 1108 in FIG. 11. Thus, the 4D model 1102, enhanced Gantt chart 1104 and the information cards 1120 can each be synchronized to the other in time. Sliding along a time axis in one of the three may display the synchronized view in the other two.

Referring back to FIG. 12, an overview information card 1210 can display a day number (e.g., since the construction project started), current time segment, total percentage complete, number of crews in operation, and number of operations at the current time segment. The overview information card 1210 can comprise other information about the status of the construction project (e.g., number of elements completed and/or in progress, number of recipes completed and/or in progress, etc.). Individual information cards (e.g., information card 1202) can display information about a specific crew, such as crew name, % work completed by the crew, operation that the crew is working on at the current time segment, and the recipe that the crew is working on at the current time segment. An individual information card can display other information about the status or involvement of the specific crew (e.g., location, equipment used, etc.). Alternatively or in addition, individual information cards can display information about a specific operation, a specific recipe, a specific element, or another specific group.

In some instances, the server may track a real progress of the construction project. For example, a real progress can indicate a completion rate of a construction element, recipe, operation, construction object, and/or construction project. In some instances, such real progress can be manually entered by a user. In some instances, an estimated progress can be confirmed as real progress by a user. In some instances, one or more machines or other devices may be able to detect, probe, and/or sense a progression rate of a construction element, object, and/or project. In some instances, the server may track a real condition or parameter of the construction project, such as a weather, atmosphere, humidity, temperature, pressure, or other condition or parameter that is capable of affecting, and/or defined as a parameter in, the construction schedule. In some instances, the server may track a real resource pool, such as real availability of different resources. Upon receipt of the real progress, real parameter or condition, and/or real resource pool of the construction project, the estimated construction schedule for the future time frame can be updated. For example, the server may re-run or re-calculate the remaining construction schedule based on remaining (e.g., future) portions of the construction plan. In some instances, the estimated construction schedule for the future time frame can be updated in real-time. Real-time can include a response time of less than 1 second, tenths of a second, hundredths of a second, or a millisecond. All of functions, such as those described above or further below, performed by the server is capable of happening in real-time. That is, the server may receive, identify, process, and output data in real-time. In some instances, a comparison between the estimated progress and real progress can be factored into a machine learning algorithm used by the server. An updated construction schedule can be presented to a user automatically or upon user instructions for an update. The updated construction schedule may be visualized, for example, by methods (e.g., graph, Gantt chart, 4D model, information cards, etc.) described elsewhere herein.

### Computer Control Systems

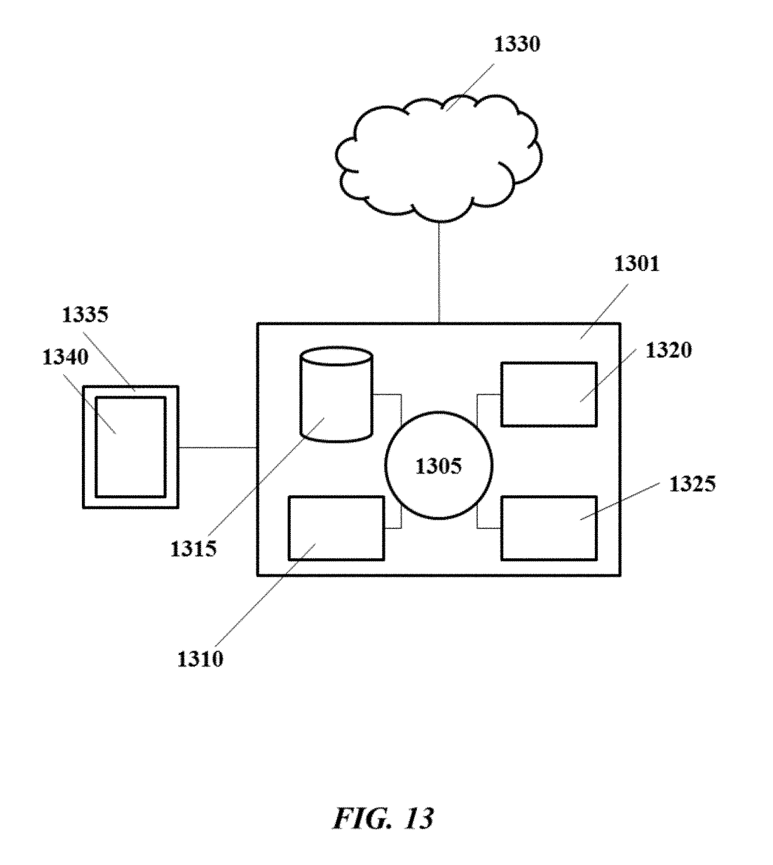

The present disclosure provides computer control systems that are programmed to implement methods of the disclosure. FIG. 13 shows a computer system 1301 that is programmed or otherwise configured to, among other actions, receive data files defining a 3D model of a construction object, analyze and process such data files, identify one or more construction elements in the construction object, determine a shape and/or dimensions of the construction elements, identify one or more support relationships between the construction elements, create, delete, and modify support relationships between the construction elements, group and split construction elements, build and access a construction recipe library, create, modify, and save construction recipes, create, modify, and save operations within a construction recipe, create, delete, and modify logical relationships between operations and/or recipes, define a resource pool, and visualize aspects of construction plans and/or schedules. The computer system 1301 can be programmed to receive and effect user input via a user interface 1340, such as a graphical user interface. The computer system 1301 can be an electronic device of a user or a computer system that is remotely located with respect to the electronic device. The electronic device can be a mobile electronic device.

The computer system 1301 includes a central processing unit (CPU, also “processor” and “computer processor” herein) 1305, which can be a single core or multi core processor, or a plurality of processors for parallel processing. The computer system 1301 also includes memory or memory location 1310 (e.g., random-access memory, read-only memory, flash memory), electronic storage unit 1315 (e.g., hard disk), communication interface 1320 (e.g., network adapter) for communicating with one or more other systems, and peripheral devices 1325, such as cache, other memory, data storage and/or electronic display adapters. The memory 1310, storage unit 1315, interface 1320 and peripheral devices 1325 are in communication with the CPU 1305 through a communication bus (solid lines), such as a motherboard. The storage unit 1315 can be a data storage unit (or data repository) for storing data. The computer system 1301 can be operatively coupled to a computer network (“network”) 1330 with the aid of the communication interface 1320. The network 1330 can be the Internet, an internet and/or extranet, or an intranet and/or extranet that is in communication with the Internet. The network 1330 in some cases is a telecommunication and/or data network. The network 1330 can include one or more computer servers, which can enable distributed computing, such as cloud computing. The network 1330, in some cases with the aid of the computer system 1301, can implement a peer-to-peer network, which may enable devices coupled to the computer system 1301 to behave as a client or a server.

The CPU 1305 can execute a sequence of machine-readable instructions, which can be embodied in a program or software. The instructions may be stored in a memory location, such as the memory 1310. The instructions can be directed to the CPU 1305, which can subsequently program or otherwise configure the CPU 1305 to implement methods of the present disclosure. Examples of operations performed by the CPU 1305 can include fetch, decode, execute, and writeback.

The CPU 1305 can be part of a circuit, such as an integrated circuit. One or more other components of the system 1301 can be included in the circuit. In some cases, the circuit is an application specific integrated circuit (ASIC).

The storage unit 1315 can store files, such as drivers, libraries and saved programs. The storage unit 1315 can store user data, e.g., user preferences and user programs. The computer system 1301 in some cases can include one or more additional data storage units that are external to the computer system 1301, such as located on a remote server that is in communication with the computer system 1301 through an intranet or the Internet.

The computer system 1301 can communicate with one or more remote computer systems through the network 1330. For instance, the computer system 1301 can communicate with a remote computer system of a user (e.g., operator, manager, administrator, worker, crew leader, etc.). Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 1301 via the network 1330.

Methods as described herein can be implemented by way of machine (e.g., computer processor) executable code stored on an electronic storage location of the computer system 1301, such as, for example, on the memory 1310 or electronic storage unit 1315. The machine executable or machine readable code can be provided in the form of software. During use, the code can be executed by the processor 1305. In some cases, the code can be retrieved from the storage unit 1315 and stored on the memory 1310 for ready access by the processor 1305. In some situations, the electronic storage unit 1315 can be precluded, and machine-executable instructions are stored on memory 1310.

The code can be pre-compiled and configured for use with a machine having a processer adapted to execute the code, or can be compiled during runtime. The code can be supplied in a programming language that can be selected to enable the code to execute in a pre-compiled or as-compiled fashion.

Aspects of the systems and methods provided herein, such as the computer system 1301, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 1301 can include or be in communication with an electronic display 1335 that comprises a user interface (UI) 1340 for providing, for example, visualization or other graphical representations of the systems and methods disclosed herein. Examples of UI's include, without limitation, a graphical user interface (GUI) and web-based user interface. For example, the user interface 1340 can be the graphical user interface 300, the graphical user interface 400, the graphical user interface 500, the graphical user interface 600, the graphical user interface 700, the graphical user interface 800, the graphical user interface 900, the graphical user interface 1000, the graphical user interface 1100, and/or the graphical user interface 1200 described elsewhere herein. The UI 1340 can be a dynamic UI. The UI 1340 can be a user interactive interface. For example, a user may provide input to the computer system 1301 through a user input interface. In some embodiments, user input interfaces may comprise user input buttons, switches, knobs, levers, keys, trackballs, touchpads, cameras, microphones, motion sensors, heat sensors, inertial sensors, touch sensors, or any combination of the above. Alternatively or in addition, the user may provide input through a touch-enabled display (e.g., touchscreen) comprising GUI.

Methods and systems of the present disclosure can be implemented by way of one or more algorithms. An algorithm can be implemented by way of software upon execution by the central processing unit 1305. The algorithm can, for example, among other functions, receive data files defining a 3D model of a construction object, analyze and process such data files, identify one or more construction elements in the construction object, determine a shape and/or dimensions of the construction elements, identify one or more support relationships between the construction elements, create, delete, and modify support relationships between the construction elements, group and split construction elements, build and access a construction recipe library, create, modify, and save construction recipes, create, modify, and save operations within a construction recipe, create, delete, and modify logical relationships between operations and/or recipes, define a resource pool, and visualize aspects of construction plans and/or schedules. The algorithm may be a machine learning algorithm that can improve accuracy or converge to a user preference with repeated iterations.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

What is claimed is:

1. A computer-implemented method for construction planning, comprising:
(a) receiving, over a computer network, at a computer system programmed to facilitate construction planning, a data file defining a 3D model of a construction object, wherein said construction object comprises one or more construction elements;
(b) determining a type and dimension values for each construction element;
(c) identifying support relationships between said one or more construction elements;
(d) assigning a construction recipe to each construction element, wherein said construction recipe defines a formula for building said construction element, wherein said formula comprises one or more operations that are logically related by one or more logical relationships, wherein an operation is defined at least by required resources, and wherein a same construction recipe is assigned to a same type of construction element;
(e) defining recipe relationships between different construction recipes for different construction elements, wherein said recipe relationship is based at least in part on said support relationships; and
(f) providing, over said computer network, to a user a construction plan comprising a plurality of construction recipes that are logically related by a plurality of recipe relationships.

2. The method of claim 1, further comprising displaying said construction recipe on a graphical user interface, each operation visualized as an independent graphical representation.

3. The method of claim 2, further comprising displaying said recipe relationships on a graphical user interface, each recipe relationship visualized as an independent graphical representation.

4. The method of claim 2, further comprising displaying said logical relationships on a graphical user interface, each logical relationship visualized as an independent graphical representation.

5. The method of claim 1, wherein said required resources is constrained by a resource pool, accessible by said computer system, defining available resources.

6. The method of claim 1, wherein said required resources is at least one of duration, production rate, equipment, material, and labor.

7. A non-transitory computer-readable medium comprising machine-executable code that, upon execution by one or more computer processors, implements a method for sharing location specific information, said method comprising:
(a) receiving, over a computer network, at a computer system programmed to facilitate construction planning, a data file defining a 3D model of a construction object, wherein said construction object comprises one or more construction elements;
(b) determining a type and dimension values for each construction element;
(c) identifying support relationships between said one or more construction elements;
(d) assigning a construction recipe to each construction element, wherein said construction recipe defines a formula for building said construction element, wherein said formula comprises one or more operations that are logically related by one or more logical relationships, wherein an operation is defined at least by required resources, and wherein a same construction recipe is assigned to a same type of construction element;
(e) defining recipe relationships between different construction recipes for different construction elements, wherein said recipe relationship is based at least in part on said support relationships; and
(f) providing, over said computer network, to a user a construction plan comprising a plurality of construction recipes that are logically related by a plurality of recipe relationships.

8. The non-transitory computer-readable medium of claim 7, wherein said method further comprises displaying said construction recipe on a graphical user interface, each operation visualized as an independent graphical representation.

9. The non-transitory computer-readable medium of claim 8, wherein said method further comprises displaying said recipe relationships on a graphical user interface, each recipe relationship visualized as an independent graphical representation.

10. The non-transitory computer-readable medium of claim 8, wherein said method further comprises displaying said logical relationships on a graphical user interface, each logical relationship visualized as an independent graphical representation.

11. The non-transitory computer-readable medium of claim 7, wherein said required resources is constrained by a resource pool, accessible by said computer system, defining available resources.

12. The non-transitory computer-readable medium of claim 7, wherein said required resources is at least one of duration, production rate, equipment, material, and labor.
